(19) United States
(12) Patent Application Publication
(10) Pub. No.: US 2015/0281601 A1
(43) Pub. Date: Oct. 1, 2015

(54) Modular Packaging and Optical System for Multi-Aperture and Multi-Spectral Camera Core

(71) Applicant: INVIS Technologies Corporation, San Jose, CA (US)

(72) Inventors: Srinivasan K. Ganapathi, Palo Alto, CA (US); Philip J. Stephanou, Mountain View, CA (US); Kurt E. Petersen, Milpitas, CA (US); John Batey, Incline Village, NV (US)

(73) Assignee: INVIS TECHNOLOGIES CORPORATION, San Jose, CA (US)

(21) Appl. No.: 14/667,198

(22) Filed: Mar. 24, 2015

Related U.S. Application Data
(60) Provisional application No. 61/970,355, filed on Mar. 25, 2014.

(51) Int. Cl. H04N 5/33; H04N 5/225; G02B 3/00; H01L 27/146

(52) U.S. Cl. CPC H04N 5/332; H01L 27/14649; H01L 27/14625; H01L 27/14634; H01L 27/14632; H01L 27/14687; H01L 27/14685; H01L 27/1469; H01L 27/14645; H04N 5/2254; G02B 3/0037; G02B 3/0075; G02B 3/0012

(57) ABSTRACT

An imaging device comprises a focal plane array (FPA) having a plurality of singulated unit cells arranged on a carrier substrate. Each of the unit cells comprises a sub-array of pixels in the focal plane array. At least one of the unit cells has a different number or type of pixels than does another one of the unit cells arranged on the carrier substrate to enable multi-spectral imaging. The device also includes at least one lens positioned to direct incident electromagnetic radiation to the unit cells. A modular method for producing the FPA and lenses of a camera core uses wafer-level packaging and optics. Lenses and sub-arrays of pixels are each fabricated on densely packed, batch-fabricated wafers, and subsequently singulated and assembled into arrays (e.g., 3×3, 4×4, 4×5) on respective low cost carrier substrates. The carrier substrates are bonded together at the substrate level to form a series of camera cores, and the stacked substrates are singulated to form individual camera cores.

### CROSS REFERENCE TO RELATED APPLICATIONS

This application claims the benefit of U.S. provisional patent application 61/970,355 filed on Mar. 25, 2014, which application is hereby incorporated by reference in its entirety.

### BACKGROUND

The invention relates to imaging devices, and in particular to a modular packaging and optical system for a multi-aperture and multi-spectral camera core.

Many existing thermal imaging solutions for night vision are based on uncooled micro-bolometer arrays that are sensitive to long wavelength infrared (LWIR) radiation in the wavelength range of about 8 to 15 μm. The infrared (IR) camera typically includes a camera core comprising a Focal Plane Array (FPA), a lens system and an enclosure. The FPA typically comprises three elements—the underlying Read-Out Integrated Circuit (ROIC), the thermistor or micro-bolometer pixel array which is built on top of the ROIC, usually on the same silicon wafer and integrated with the ROIC, and a “packaged window” or lid which is substantially transparent to incoming IR radiation from a source and bonded on top of the FPA with a hermetic vacuum seal. Finally, a single lens or a system of lenses is mounted on top of the FPA.

Typically, the optical lens system can be quite complex and involve multiple lens elements. In the case of IR imaging optics, the lens material is usually made through diamond point turning of germanium, which can be a very expensive process. Traditionally, the approach chosen to enable vacuum has been to use a crystalline germanium lid, and bond it to the FPA package. In order to minimize stresses due to differential coefficients of expansion, the FPA wafer is first singulated into die and mounted on a ceramic package. The germanium lid is then bonded to the ceramic package under very high vacuum. In spite of its high cost, germanium is selected as a lid material because of its low attenuation of infrared light in the relevant range of wavelengths.

Consequently, many micro-bolometer devices currently available for thermal imaging are bulky, extremely expensive, and largely restricted to special use cases such as military or high-end automotive applications. Many night vision cameras today cost several thousands of dollars apiece, making their integration into mid- and low-range priced applications prohibitive. There is still a need for a night vision thermal imaging camera core that enables a small form factor and low cost while maintaining adequate performance. This would enable usage of thermal imaging in expanded security, surveillance, first responder and a wider range of automotive applications.

### SUMMARY

According to one aspect, a method is provided for producing a focal plane array of pixels for detecting electromagnetic radiation. The method comprising the steps of batch-fabricating a plurality of unit cells on at least one wafer. Each of the unit cells comprises a sub-array of pixels, and adjacent unit cells have a first spacing from each other on the wafer. The method also comprises singulating the unit cells, and arranging individual ones of the singulated unit cells into a group on a carrier substrate such that the spacing between adjacent unit cells on the carrier substrate is greater than the first spacing on the wafer.

According to another aspect, an imaging device comprises a focal plane array having a plurality of singulated unit cells arranged on a carrier substrate. Each of the unit cells comprises a sub-array of pixels in the focal plane array. At least one of the unit cells has a different number or type of pixels than does another one of the unit cells arranged on the carrier substrate. The device also includes at least one lens positioned to direct incident electromagnetic radiation to the unit cells.

According to another aspect, a method is provided for producing a lens array. The method comprises the steps of batch-fabricating a plurality of lenslets on one or more wafers. The method also comprises singulating the lenslets, and forming the lens array by arranging a plurality of the singulated lenslets on a carrier substrate

### BRIEF DESCRIPTION OF THE DRAWINGS

The foregoing aspects and advantages of the present invention will become better understood upon reading the following detailed description and upon reference to the drawings where:

FIG. 1 is an exploded, isometric view of a wafer stack comprising a plurality of camera cores having standoffs for maintaining a desired separation between the FPA carrier and lenslet carrier substrates.

FIG. 2 is a cross-sectional view of a camera core according to another embodiment having a single lens for directing incident electromagnetic radiation to respective sub-arrays of pixels.

FIG. 3 is a top plan view of a densely packed FPA wafer that is singulated along “dicing streets” to form individual FPA “unit cells” according to some embodiments of the invention.

FIG. 4 is a top plan view of a FPA unit cell having a plurality of pixels and bond pads for electrical connections according to some embodiments of the invention.

FIG. 5 is a partially exploded, isometric view of an assembly process used to form focal plane arrays on a FPA carrier substrate using singulated FPA unit cells according to some embodiments of the invention.

FIG. 6 is a top plan view of a 3×3 array of FPA unit cells densely packed on a wafer.

FIG. 7 is a top plan view of a 3×3 array of singulated FPA unit cells arranged with greater spacing between adjacent unit cells on a carrier substrate and corresponding lenslets positioned to direct incident electromagnetic radiation to the unit cells, according to some embodiments of the invention.

FIG. 8 is a schematic block diagram showing an example of multiplexing multiple FPA sub-arrays to a common digital signal processor, according to some embodiments of the invention.

FIG. 9 is a top plan view of a densely packed wafer of batch-fabricated lenslets that is singulated along “dicing streets” to form individual lenslets.

FIG. 10 is a partially exploded, isometric view of an assembly process used to form lens arrays on a carrier substrate using singulated lenslets.

FIG. 11 is a partially cut-away, isometric view of through “window” and “shelf” or “ledge” features for supporting lenslets on a carrier substrate according to some embodiments of the invention.

FIG. 12 is a bottom plan view of a lens carrier substrate showing bonding rings surrounding each lenslet array, according to some embodiments of the invention.

FIG. 13 is a top plan view of a 3×3 array of batch-fabricated lenslets that are densely packed on a wafer to maximize wafer utilization.

FIG. 14 is a top plan view of a 3×3 array of lenslets arranged with greater spacing between adjacent lenslets on a lens carrier substrate with border area to accommodate separation between FPA pixel sub-arrays, according to some embodiments of the invention.

FIG. 15 is a cutaway view of a bonded substrate stack to be diced to produce individual camera cores, according to some embodiments of the invention.

FIG. 16 is a plan view of a camera core die showing the alignment between FPA unit cells having sub-arrays of pixels and corresponding lenslets arranged to direct incident electromagnetic radiation to the pixels, according to some embodiments of the invention.

FIG. 17 is a cross-sectional view of another camera core having multiple standoffs arranged to hold multiple lenses that direct incident electromagnetic radiation to pixels in the focal plane array, according to some embodiments of the invention.

FIG. 18 is a flow diagram illustrating steps in an assembly process for camera cores, according to some embodiments of the invention.

### DETAILED DESCRIPTION OF PREFERRED EMBODIMENTS

In the following description, it is understood that all recited connections between structures can be direct operative connections or indirect operative connections through intermediary structures. A set of elements includes one or more elements. Any recitation of an element is understood to refer to at least one element. A plurality of elements includes at least two elements. Unless otherwise required, any described method steps need not be necessarily performed in a particular illustrated order. A first element (e.g. a signal or data) derived from a second element encompasses a first element equal to the second element, as well as a first element generated by processing the second element and optionally other data. Making a determination or decision according to a parameter encompasses making the determination or decision according to the parameter and optionally according to other data. Unless otherwise specified, an indicator of some quantity/data may be the quantity/data itself, or an indicator different from the quantity/data itself. Computer programs described in some embodiments of the present invention may be stand-alone software entities or sub-entities (e.g., subroutines, code objects) of other computer programs. Computer readable media encompass non-transitory media such as magnetic, optic, and semiconductor storage media (e.g. hard drives, optical disks, flash memory, DRAM), as well as communications links such as conductive cables and fiber optic links According to some embodiments, the present invention provides, inter alia, computer systems comprising hardware (e.g. one or more processors and associated memory) programmed to perform the methods described herein, as well as computer-readable media encoding instructions to perform the methods described herein.

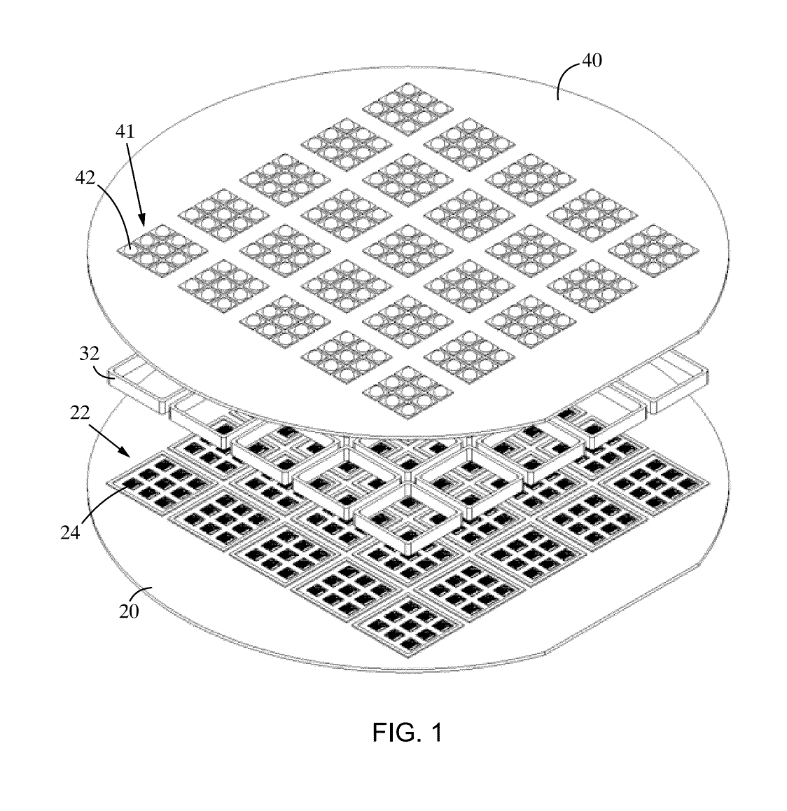

FIG. 1 shows an exploded view of an enhanced, modular packaging and optical system for twenty-five micro-bolometer-based camera cores (e.g., a 5×5 array of camera cores for purposes of illustration). Each camera core includes a focal plane array (FPA) 22 comprising multiple sub-arrays 24 of pixels assembled into a desired sub-array configuration (e.g., 3×3, 4×4, 4×5). Each camera core also includes a lens array 41 having a plurality of lenses 42. Each of the lenses 42 is preferably positioned to direct incident electromagnetic radiation to a corresponding one of the pixel sub-arrays 24. A desired separation (e.g., the focal length of the lenses 42) is maintained between each of the lens arrays 41 and its corresponding FPA 22 by means of a corresponding spacer or standoff structure 32.

A modular, substrate-level approach that uses wafer-level processing (WLP) is preferably used to form the focal plane array (FPA) 22 and the lens array 41 of each camera core. In some embodiments, each of the camera cores supports multi-spectral, super-resolution or plenoptic imaging. The micro-bolometer pixels are grouped into sub-arrays 24 of pixels, and incident electromagnetic radiation is directed (e.g., focused) onto each sub-array 24 of pixels by a corresponding micro-lens or “lenslet” 42 within the lens array 41.

The FPA sub-arrays 24 are preferably fabricated on densely packed, batch fabricated wafers, and subsequently singulated and assembled into the desired sub-array configurations (e.g., 3×3, 4×4, 4×5) on a low cost carrier substrate 20. Similarly, the lenslets 42 may be fabricated on densely packed, batch fabricated wafers, and subsequently singulated and assembled into the desired lens array configurations (e.g., 3×3, 4×4, 4×5) on a low cost carrier substrate 40. The FPA carrier substrate 20 carrying each FPA 22 and the lens carrier substrate 40 carrying each lens array 41, along with the standoff structures 32 corresponding to each FPA 22 and lens array 41, are bonded together at the substrate level to form an array of camera cores. The stacked substrates 20, 40 are then singulated (for example using a dicing saw) to form twenty-five individual camera cores.

These methods maximize the number of die that can fit on a wafer of a given size, and thus reduce the cost per camera core. Providing the requisite inter-FPA sub-array and inter-lenslet spacing is relegated to the relatively inexpensive carrier substrates 20, 40. The FPA carrier substrate 20 may include elements to enable substrate-substrate bonding, signal routing, an integrated circuit (IC), and signal multiplexing and demultiplexing. Furthermore, the lenslet carrier substrate 40 also preferably serves as part of the vacuum package, thereby obviating the need for a separate WLP and/or lid.

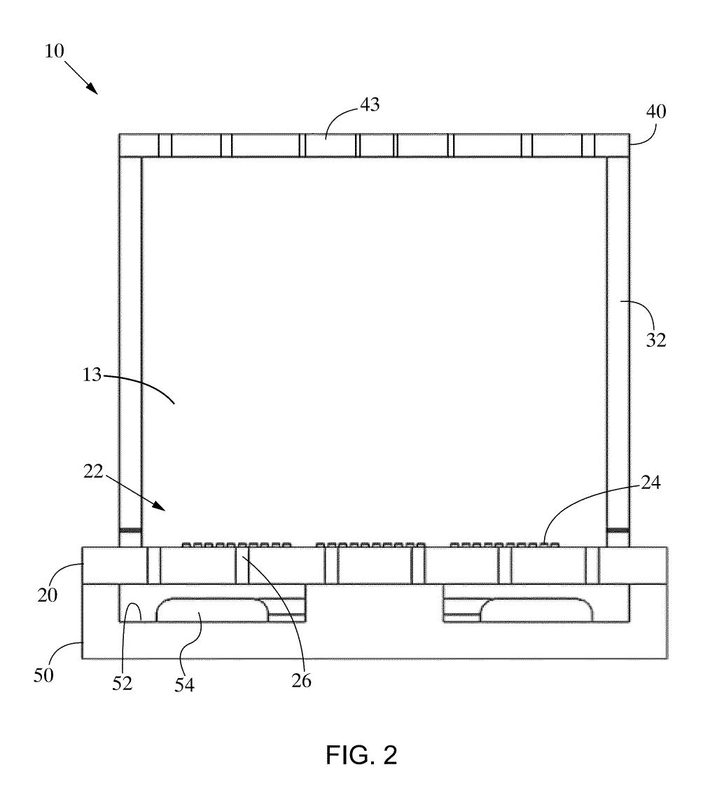

FIG. 2 shows a schematic, cross-sectional view of a thermal imaging device 10 according to some embodiments of the present invention. The device 10 includes the FPA 22 formed on the FPA carrier substrate 20. The FPA 22 comprises a plurality of sub-arrays 24 of pixels. The device 10 also includes at least one lens substrate 40 holding at least one lens 43. The lens 43 is arranged to direct incident electromagnetic radiation (e.g., infrared rays) to focused spots on the sub-arrays 24 of pixels. In this embodiment, the lens 43 is preferably a single gradient-index (GRIN) lens. In other embodiments, the lens substrate 40 supports an array of lenslets. The standoff structure 32 spaces the lens 43 at a desired separation from the FPA 22. The separation of the lens 43 from the pixel sub-arrays 24 preferably provides an optical path length in the range of 2 to 14 mm from the lens 43 to the pixels. The standoff structure 32 may be patterned, for example, from silicon (e.g., by DRIE of a SOI wafer), a metal, ceramic, glass or polymer.

The lens carrier substrate 40 encloses the FPA 22 in a vacuum in a space 13 between the lens carrier substrate 40 and the FPA carrier substrate 20. The term vacuum is intended to mean a space in which the pressure is lower than atmospheric pressure. In some embodiments, the standoff structure 32 forms the substantially vertical walls around the periphery of the enclosed space 13 containing the FPA 22 between the lens substrate 40 and the FPA substrate 20. A hermetic seal may be formed, for example, using a fusion bonding process. In other embodiments, the lens substrate 40 is attached directly to the FPA substrate 20. The lens substrate 40 preferably has a thickness in the range of 250 to 2000 μm to impart bending stiffness and to resist excessive deflection. In some embodiments, the device 10 optionally includes a cavity substrate 50 attached to the FPA substrate 20. The cavity substrate 50 has one or more cavities 52 in fluid communication with the enclosed space 13 by means of vias 26 in the FPA carrier substrate 20. Maintaining a desired level of vacuum (e.g., a pressure in the range of 0.1 to 100 mTorr) may optionally be aided by putting getter material 54 in the cavities 52. The getter material may comprise, for example, an alloy containing zirconium and one or more of vanadium, cobalt, iron, aluminum, or titanium.

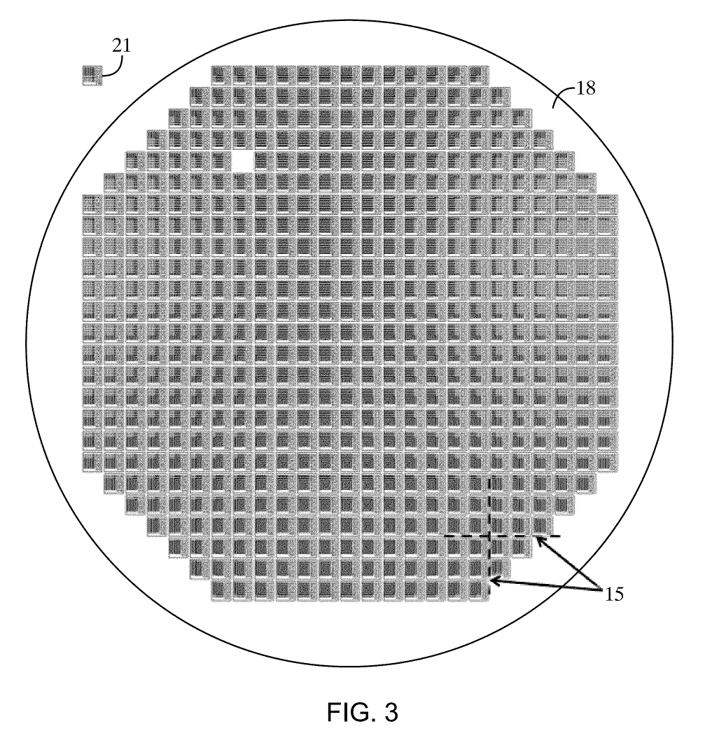

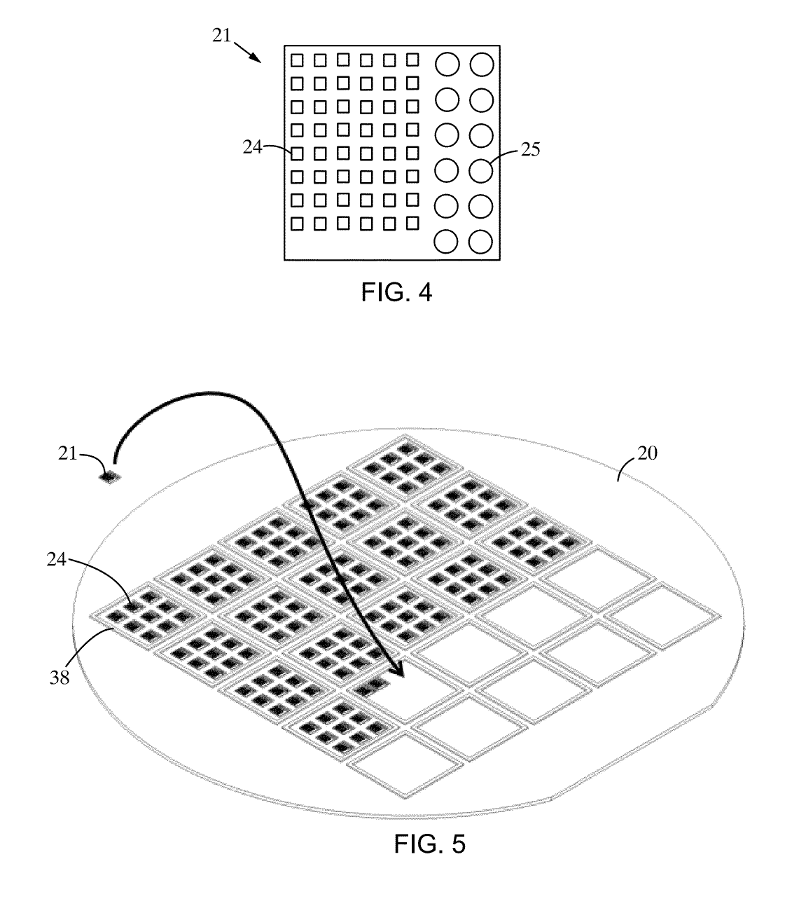

FIG. 3 is a top plan view of a densely packed FPA wafer 18 that is singulated along “dicing streets” 15 (indicated by dashed lines) to form individual FPA “unit cells” 21 according to some embodiments of the invention. An FPA preferably comprises a read-out integrated circuit (ROIC) and a micro-electromechanical systems (MEMS) micro-bolometer array. Typically, a series of ROICs is formed on a 150 mm or 200 mm diameter, single crystal silicon (Si) wafer using traditional semiconductor batch fabrication processes (e.g., photolithographic pattern reproduction, wet etching, reactive and physical dry etching, dopant implantation, thin film deposition, etc.), and a MEMS micro-bolometer device (comprising active and reference pixel arrays, signal routing lines, bonding pads, etc.) is subsequently fabricated directly atop each ROIC using MEMS batch fabrication techniques. In multi-aperture camera cores configured to support super-resolution or plenoptic imaging, the FPA is configured as an array of micro-bolometer pixel sub-arrays. A series of FPA sub-arrays are formed on the wafer 18 using traditional MEMS batch fabrication processes, and the wafer 18 is singulated (using, for example, a dicing process) into discrete FPA sub-array die that provide unit cells 21 for the focal plane array. FIG. 4 is a top plan view of a FPA unit cell 21 comprising a sub-array 24 of pixels (e.g., a 6×8 pixel sub-array) and bond pads 25 for electrical connections.

FIG. 5 is a partially exploded, isometric view of an assembly process used to form focal plane arrays on the FPA carrier substrate 20 using singulated FPA unit cells 21, according to some embodiments of the invention. Individual unit cell die 21 are assembled on the FPA carrier substrate 20 to form an array of FPA pixel sub-arrays 24 of the desired configuration such as, for example, 3×3, 4×4, or 4×5. Accordingly, the area for a bonding ring 38 and inter-sub-array spacing are relegated to the relatively low cost FPA carrier substrate 20, thereby allowing more FPA unit cells 21 to be packed on a given wafer and singulated as FPA sub-array die, and thus reducing the overall cost of a camera core. The bonding ring 38 may be formed using, for example, a metal, silicon, or an oxide or a nitride of silicon.

The FPA unit cells 21 may be positioned on the FPA carrier substrate 20 using, for example, a pick and place or fluidic self-assembly process. Electrical connections for routing power and signals between the FPA unit cells 21 and the carrier substrate 20 may be made using, for example, wirebonds or through-silicon vias (TSV) and corresponding bond pads. In some embodiments, the FPA carrier substrate comprises bonding pads to accommodate wirebonds or TSVs, routing for electrical signals and power, and ICs. Some examples of ICs may include circuits for power conditioning, signal processing, analog-to-digital converters (ADC), volatile or non-volatile digital memory, and multiplexing and demultiplexing. The FPA carrier substrate 20 may be formed using, for example, silicon, glass, a ceramic, or a polymer, and may further comprise multiple, electrically isolated layers to support multi-layer signal routing.

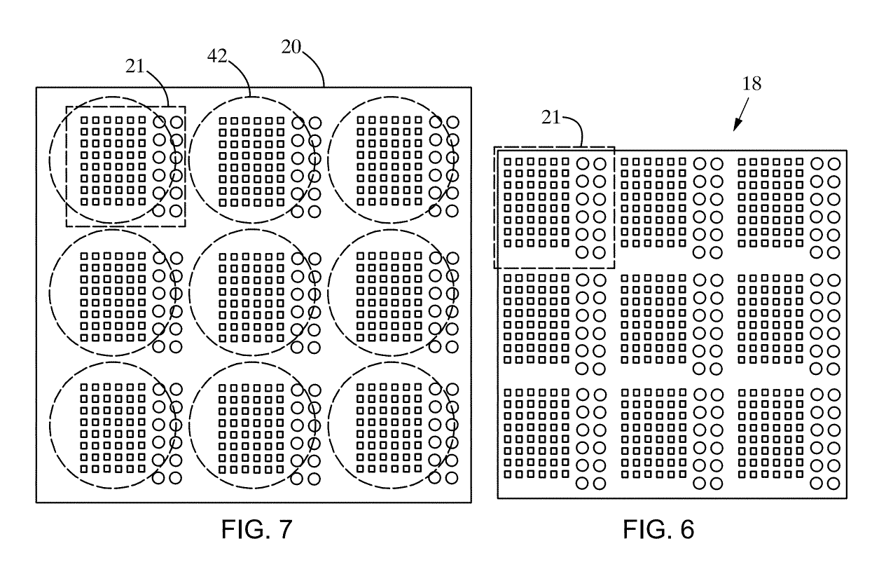

FIG. 6 shows a top plan view of a 3×3 array of FPA unit cells 21 (indicated by the dashed lines) that are densely packed on a portion of the wafer 18. FIG. 7 is a top plan view of a 3×3 array of singulated FPA unit cells arranged with greater spacing between adjacent unit cells on the carrier substrate 20. Corresponding lenslets 42 are positioned to direct incident electromagnetic radiation to the unit cells 21. In some embodiments, the focal plane array on the FPA carrier substrate 20 comprises substantially identical FPA unit cells of pixel sub-arrays. In other embodiments, the array comprises different unit cell die, such as different micro-bolometer sub-arrays of pixels in terms of pixel count, coatings, sensitivity to different wavelength ranges of light, etc. In some embodiments, at least one of the unit cells comprises a sub-array of pixels sensitive to long wavelength infrared (LWIR) radiation, and at least one other of the unit cells comprises a sub-array of pixels that is sensitive to visible light, near-infrared (NIR) radiation, or ultraviolet (UV) radiation to enable multi-spectral imaging.

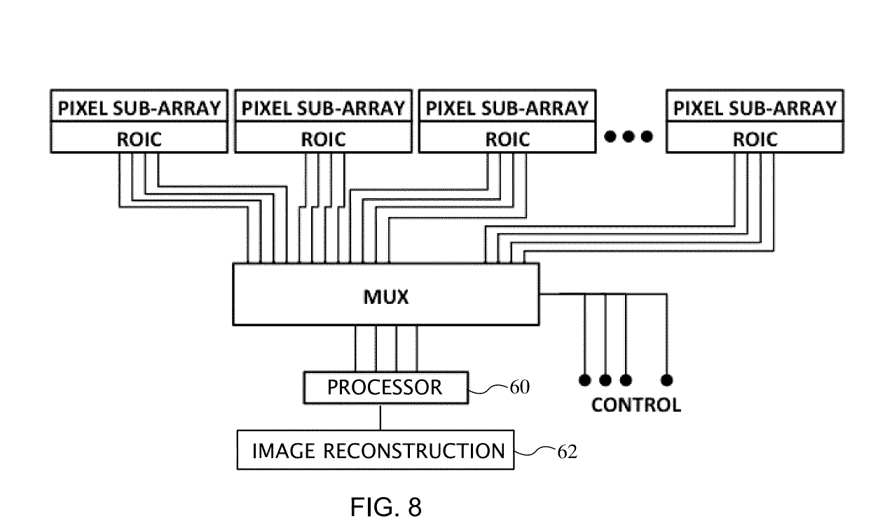

FIG. 8 is a schematic block diagram showing an example of multiplexing multiple FPA unit cells including pixel sub-arrays and corresponding ROIC to a common digital signal processor 60, according to some embodiments of the invention. Multiplexing may be leveraged to reduce the FPA sub-array die size, and hence the overall system cost by using common circuitry to address more than one FPA unit cell. The ICs may be fabricated monolithically on the FPA carrier substrate, or fabricated separately and attached to the FPA carrier substrate using, for example, wirebonds or flip-chip bonding.

An imaging device can be configured to process scene data from all available pixels to achieve the highest possible resolution, or from a subset of the pixels to reduce power consumption, depending on the user's requirements. The use of multiple apertures that are at least partially overlapping provides an “oversampling” of the image. Therefore, even if the image from one of the pixels is defective (e.g., due to mis-calibration of the pixels during field operation, defects during manufacturing, or failures in the field), the resulting digitally reconstructed image can compensate for that based on the information from the remaining functional pixels. The processor 60 receives signals or data from the readout integrated circuits and executes an image reconstruction program 62 to construct a higher resolution image from the multiple low-resolution images from the various pixel sub-arrays. Examples of suitable image reconstruction programs are those used in multi-spectral, super-resolution, and/or plenoptic imaging schemes.

In some multi-aperture camera cores configured to support super-resolution or plenoptic imaging, the lens system comprises an array of micro-lenses or “lenslets”. Each lenslet focuses incident electromagnetic radiation from a remote scene onto a corresponding pixel sub-array. When configured for imaging LWIR, the lenslets may be formed using point-turned germanium (Ge), a molded material such as chalcogenide glass or zinc sulfide (ZnS), or an etched material such as silicon. In some embodiments, the lenslets may be configured to further support imaging other types of electromagnetic radiation such as NIR and visible light. In the case of molded and etched lenslets, the lenslets may be formed as individual lenslets, as a monolithic lenslet array, or as a monolithic array of lenslet arrays. In some embodiments, a border area is provided around each lenslet to accommodate a rectangular pixel array inscribed within a circular lenslet.

In some etched lens configurations, the etched lenses are configured to support focusing incident electromagnetic radiation using refraction. Examples of refractive optical elements include surface profile elements and Gradient Index (GRIN) elements. In other etched lens configurations, the etched lenses are configured to support focusing incident electromagnetic radiation using diffraction. An example of a diffractive optical element is a Fresnel lens. In still other etched lens configurations, the etched lenses are configured to support focusing incident electromagnetic radiation using both refraction and diffraction.

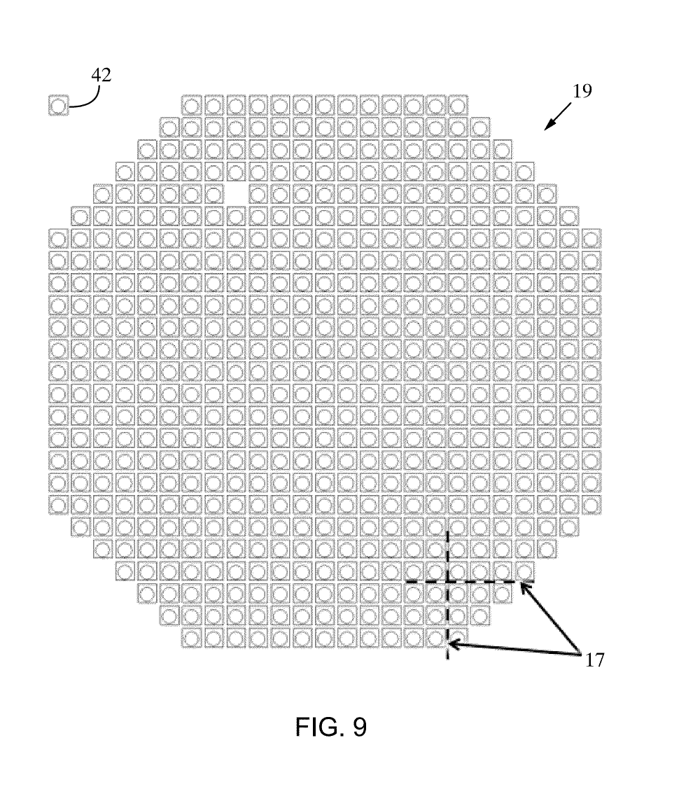

FIG. 9 is a top plan view of a densely packed wafer 19 of batch-fabricated lenslets that is singulated along “dicing streets” 17 (represented by dashed lines) to form individual lenslets 42. In some embodiments, the lenslets 42 are formed on the wafer 19 (using, for example, Si) using traditional micro-opto-electromechanical systems (MOEMS) batch fabrication processes. The wafer 19 is singulated (using, for example, a dicing process) into discrete lenslet die 42.

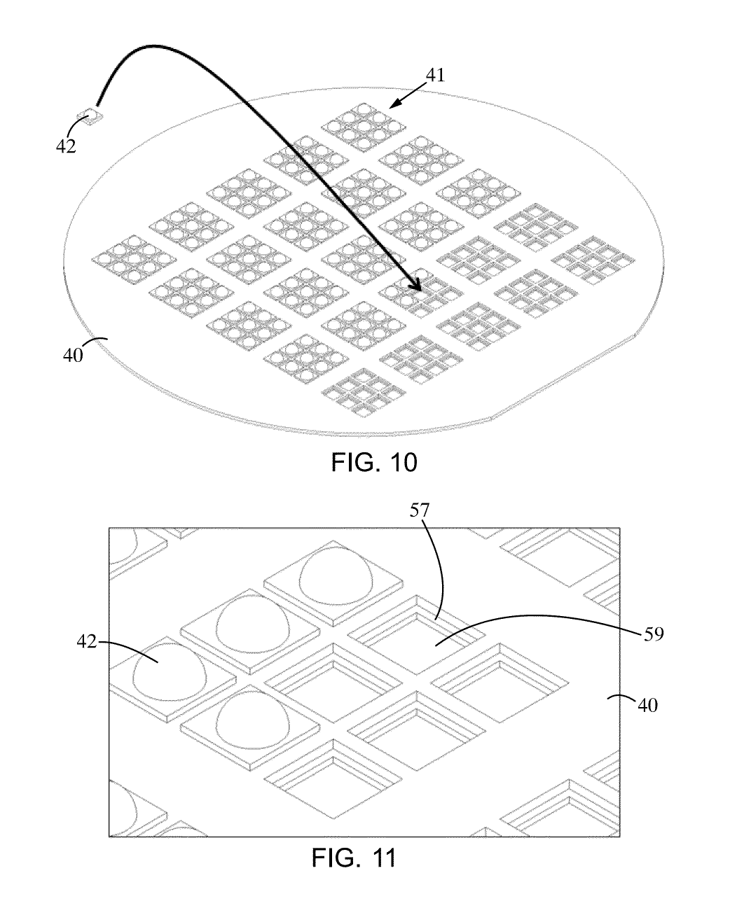

FIG. 10 shows an assembly process used to form the lens array 41 on the lens carrier substrate 40 using singulated lenslets 42. Individual lenslet die 42 are assembled on the lens carrier substrate 40 to form an array 41 of lenslets of the desired configuration such as, for example, 3×3, 4×4, or 4×5. Accordingly, the area for the inter-lenslet spacing is relegated to the relatively low cost lens carrier substrate 40, thereby allowing more lenslet die to be packed on a given wafer, and thus reducing the overall cost of a camera core. The lenslets 42 may be positioned on the lenslet carrier substrate 40 using, for example, a pick and place process. The lenslet carrier substrate 40 may be formed using silicon, glass, a ceramic, a metal, or a polymer.

FIG. 11 is a partially cut-away, isometric view of through “window” and “shelf” or “ledge” features for supporting lenslets 42 on the lens carrier substrate 40, according to some embodiments of the invention. The lenslet carrier substrate 40 comprises an array of lenslet carrier cells. Each lenslet carrier cell includes “shelf” or “ledge” structures 57 formed on a first surface of the carrier substrate 40 to align and support a respective lenslet 42, and a through “window” 59 to pass incident electromagnetic radiation.

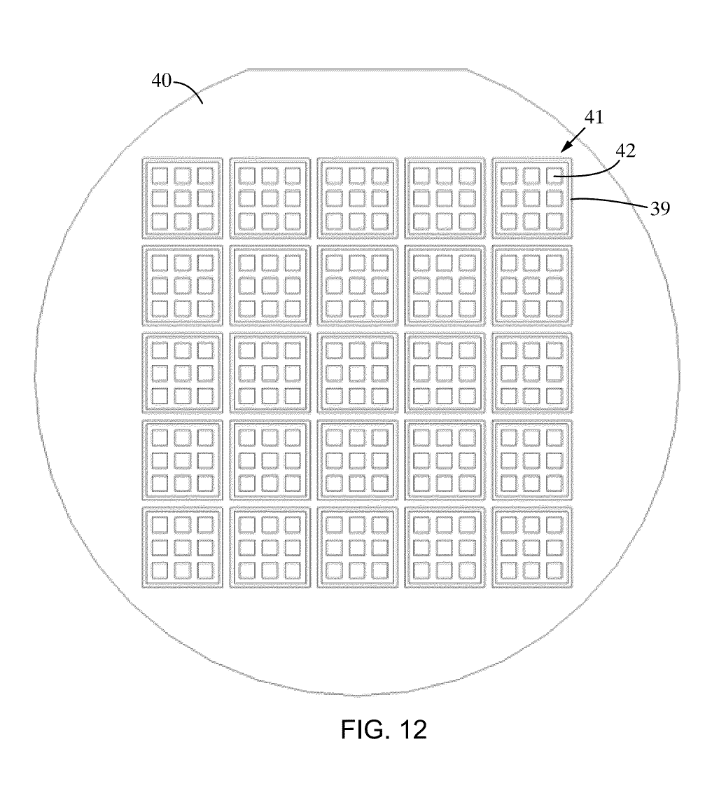

FIG. 12 is a bottom plan view of the lens carrier substrate 40 showing bonding rings 39 surrounding each lenslet array 41, according to some embodiments of the invention. The bonding rings 39 are useful for bonding the lens carrier substrate 40 to standoff structures that space the lenslets from the pixels of a focal plane array. The bonding rings 39 may be formed using, for example, a metal, silicon, or an oxide or a nitride of silicon formed on a second surface of the lens carrier substrate 40. In some embodiments, the lenslets 42 are attached to the lenslet carrier substrate 40 using a hermetic bond formed using, for example, a fusion bonding or solder process. In configurations using a hermetic bond between the lenslets 42 and the lenslet carrier substrate 40, the lenslet carrier substrate assembly may serve as part of the vacuum package, thereby obviating the need for a separate package lid.

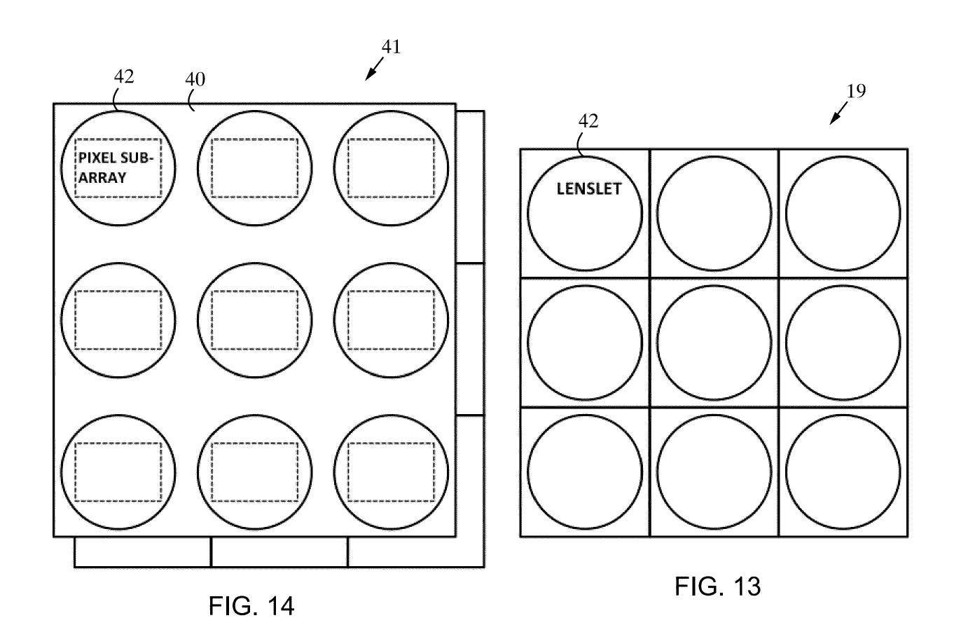

FIG. 13 is a top plan view of a 3×3 array of batch-fabricated lenslets 42 that are densely packed on the wafer 19 to maximize wafer utilization. FIG. 14 is a top plan view of a 3×3 array of lenslets 42 arranged with greater spacing between adjacent lenslets on the lens carrier substrate 40 with border area to accommodate separation between FPA pixel sub-arrays. In some embodiments, the lens array 41 comprises substantially identical lenslet die. In other embodiments, the lens array 41 comprises different die such as, for example, lenslets having different relative aperture (F/#), optical axis orientation, material composition, or diameter. Accordingly, in configurations of the imaging system using a combination of LWIR, NIR, UV and/or visible light-sensitive detector die to form the sub-arrays of pixels, the lenslet corresponding to each LWIR-sensitive detector may be formed using, for example, silicon or chalcogenide glass, and the lenslet corresponding to each NIR, UV and/or visible light-sensitive detector may be formed using, for example, a glass or a polymer.

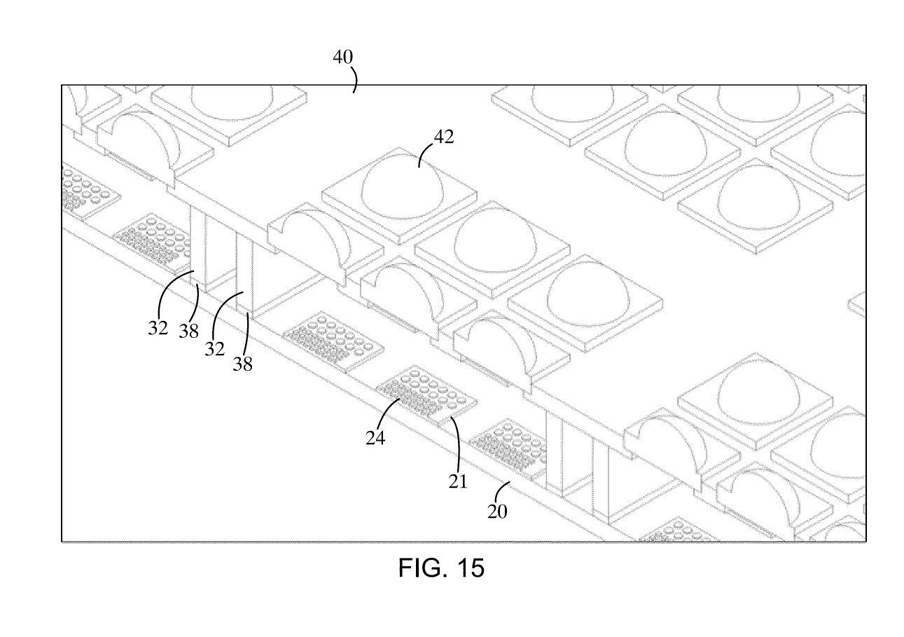

FIG. 15 is a cutaway view of a bonded substrate stack including the FPA carrier substrate 20 and the lens carrier substrate 40. In some traditional LWIR camera core configurations using a WLP scheme, an optically transmissive lid (formed using, for example, Ge or Si) is provided as part of the overall vacuum package that serves as a window for incident IR radiation. In some embodiments of the present invention, the lenslet carrier substrate 40 effectively takes the place of a separate lid wafer as part of the WLP. A series of spacer or standoff structures 32 are used to form the lateral “walls” of the vacuum space containing the focal plane array between the FPA carrier substrate 20 and the lens carrier substrate 40. The standoff structures 32 also maintain the appropriate separation (along the optical axis) between the pixel sub-arrays 24 on the FPA carrier substrate 20 and the corresponding lenslets 42 on the lens carrier substrate 40. The height of the standoff structures 32 may be chosen to correspond substantially to the focal length of the lenslets 42 (e.g., 2 to 14 mm).

In some embodiments, the standoff structures 32 are placed and bonded around the pixel sub-arrays 24 on the FPA carrier substrate 20, and the lenslet carrier substrate 40 is placed and bonded to the assembly at the standoffs 32 such that each lenslet is substantially aligned to a corresponding FPA sub-array 24 of pixels. In other embodiments, the standoffs 32 may first be placed and bonded around each lenslet array on the lenslet carrier substrate 40 (e.g., to the bonding rings 39 in FIG. 12). Referring again to FIG. 15, the FPA carrier substrate 20 is subsequently placed and bonded to the assembly at the standoffs 32. In either embodiment, the standoffs 32 may be placed using, for example, a pick and place process. The bonds between the FPA carrier substrate 20 and the standoffs 32 and between the standoffs 32 and the lenslet carrier substrate 40 may be formed using, for example, a solder or fusion bonding process. The standoffs 32 may be formed using a material such as, for example, a metal, ceramic, polymer, or combinations thereof.

In order to minimize heat transfer between the micro-bolometer pixels and the ambient environment through convection, the FPA is preferably packaged under a vacuum. Thus, the bonds between the FPA carrier substrate 20 and standoffs 32, the standoffs 32 and lenslet carrier substrate 40, and the lenslets 42 and lenslet carrier substrate 40 should be substantially hermetic. Two approaches to achieve the desired level of vacuum within the disclosed WLP include: (1) the FPA carrier substrate 20, standoffs 32 and lenslet carrier substrate 40 may be assembled and bonded (as described above) to form hermetic seals in a vacuum environment; or (2) the FPA carrier substrate 20, standoffs 32 and lenslet carrier substrate 40 may be assembled and bonded such that a fluidic “port” remains between the packaged volume and ambient environment, and the package assembly is subsequently evacuated in a vacuum environment and the port hermetically sealed. In some embodiments, the standoffs 32 are designed to mitigate the temperature sensitivity of the overall camera core. For example, the material of a standoff may be chosen such that the temperature coefficient of expansion of the resulting standoff offsets the temperature coefficient of index of refraction of a lenslet 42.

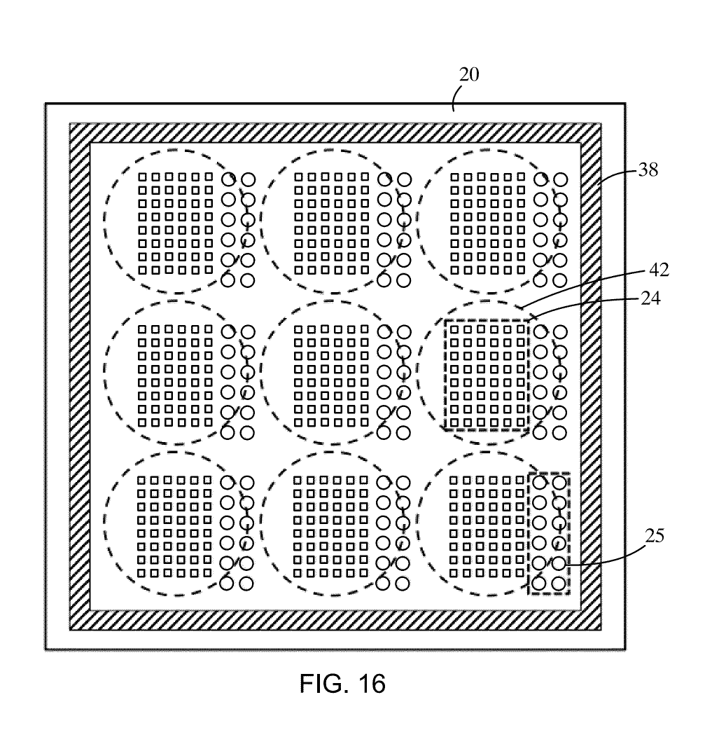

FIG. 16 is a plan view of a camera core die showing the alignment between FPA unit cells having bond pads 25, sub-arrays 24 of pixels, and corresponding lenslets 42 arranged to direct incident electromagnetic radiation to the pixel sub-arrays 24. The inter-FPA sub-array spacing (required to inscribe rectangular pixel sub-arrays 24 within circular lenslets 42) and bonding ring 38 (for forming a WLVP) are relegated to the relatively inexpensive FPA carrier substrate 20. Further area reduction of the FPA die may be achieved in some configurations by replacing portions of the ROIC on each die with common, multiplexed ROICs on the FPA carrier substrate 20.

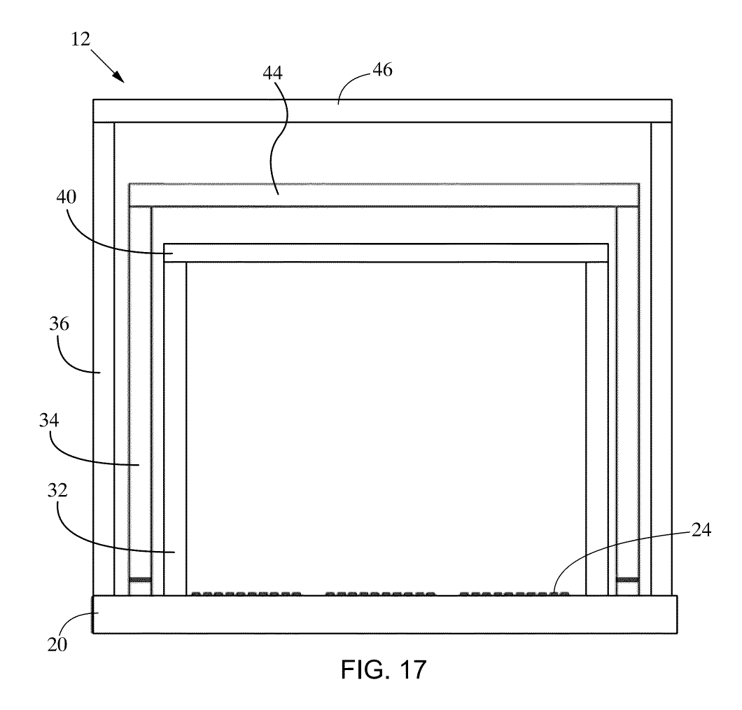

FIG. 17 is a cross-sectional view of another camera core having multiple spacers or standoffs 32, 34 and 36 and multiple lens carrier substrates 40, 44 and 46 that are arranged to hold multiple lenses or multiple arrays of lenses, according to some embodiments of the invention. The camera core further comprises a second lenslet carrier substrate 44 spaced from the pixel sub-arrays 24 by a second set of standoffs 34. In some embodiments, the second standoff structure 34 is placed and bonded around the first standoff 32, and the second lenslet carrier substrate 44 is placed and bonded to the resulting assembly at the second standoffs 34. The bonds between respective lenslet carrier substrates and standoffs may be formed using, for example, a solder or fusion bonding process. The standoffs may be formed using a material such as, for example, a metal, ceramic, polymer, or combinations thereof. In some embodiments, the camera core may further comprise a third lenslet array carrier substrate 46 and a third set of standoffs 36, a fourth lenslet array carrier substrate and a fourth set of standoffs, and so forth. These embodiments are useful when it is desirable to use multiple lenses or multiple arrays of lenses (held by multiple lens carrier substrates) that substantially share an optical axis to direct incident electromagnetic radiation to the pixel sub-arrays 24.

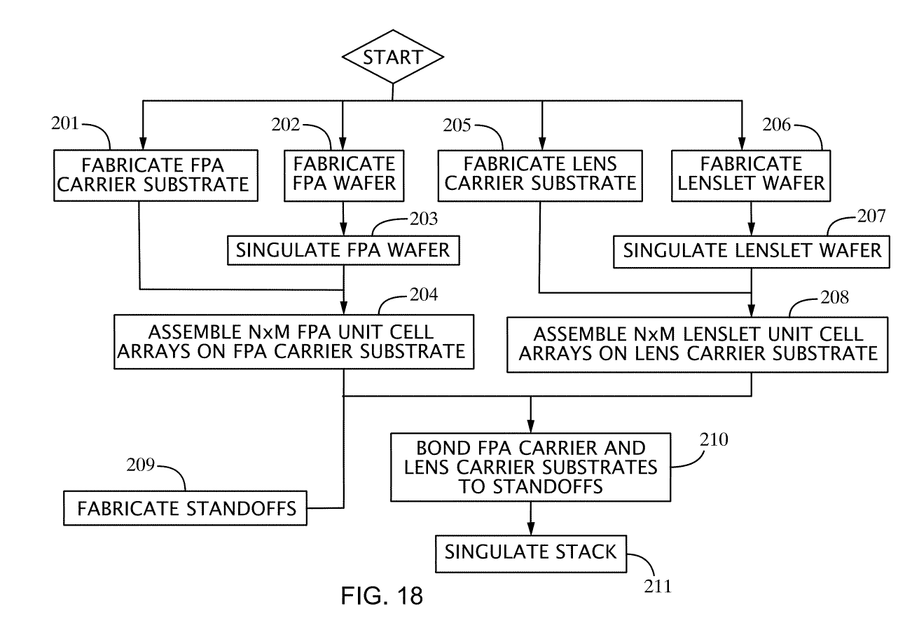

FIG. 18 shows a flow diagram representation of a possible process for assembling the camera core using at least one FPA wafer, FPA carrier substrate, lenslet wafer, lenslet carrier substrate, and standoffs. In step 201, the FPA carrier substrate is fabricated. The FPA carrier substrate may include elements to enable substrate-substrate bonding, signal routing, an integrated circuit (IC), and signal multiplexing and demultiplexing. In step 202, the FPA unit cells with pixel sub-arrays are fabricated on at least one densely packed, batch fabricated wafer. In step 203, the FPA unit cells are singulated. In step 204, the singulated FPA unit cells are assembled into the desired sub-array configurations (e.g., 3×3, 4×4, 4×5) on the FPA carrier substrate. In step 205, the lens carrier substrate is fabricated. In step 206, the lenslets are fabricated on at least one densely packed, batch-fabricated wafer. In step 207, the lenslets are singulated. In step 208, the lenslets are assembled into the desired lens array configurations (e.g., 3×3, 4×4, 4×5) on the lens carrier substrate.

In step 209, the standoffs are fabricated. The standoffs may be fabricated using traditional precision manufacturing tools and processes such as, for example, extruding, electrical discharge machining (EDM), injection molding, casting, media blasting, computer numerical control (CNC) machining, stamping, etc. In step 210, the FPA carrier substrate, the lens carrier substrate, and the standoffs are bonded together at the substrate level to form an array of camera cores. In step 211, the stacked substrates are singulated (for example using a dicing saw) to form individual camera cores.

The description above illustrates embodiments of the invention by way of example and not necessarily by way of limitation. Many other embodiments and variations of the modular system are possible. For example, the use of nominally identical “unit cells” for the FPA pixel sub-arrays and lenslets allows camera cores supporting different resolutions (e.g., QVGA, VGA, XGA, etc.) to be created using the same mask sets for the detector and lens batch fabrication processes by simply scaling the number of arrayed unit cells. For example, changing from a 3×3 array of FPA sub-arrays and corresponding 3×3 array of lenslets to a 4×4 array of FPA sub-arrays and corresponding 4×4 array of lenslets can increase the effective resolution of the resulting camera core. Only the mask sets used to fabricate the FPA carrier and lenslet carrier substrates, each comprising fewer masks than the mask sets used to fabricate the FPA sub-arrays and lenslets (and moreover requiring only standard semiconductor fabrication processes that may be easily outsourced to commercial foundries), need to be tailored to a particular camera configuration.

A pick and place process used to arrange the sub-arrays of pixels on the FPA carrier substrate can intersperse different detector die (e.g., different sub-arrays of pixels), including visible light-sensitive detector die (such as, for example, CMOS visible light detectors) and NIR-sensitive detector die (such as, for example, CMOS or micro-bolometer NIR detectors) with LWIR-sensitive detector die (such as, for example, micro-bolometer detectors). The visible light detector die typically provides high resolution and low cost and can be used, in conjunction with image reconstruction algorithms, to enable multi-spectral imaging or to enhance image resolution in the presence of visible light. In some embodiments, the FPA carrier substrate may incorporate one or more FPA unit cells of pixel sub-arrays that differ from the other FPA unit cells in terms of pixel count, coatings, or pixel size. The present approach enables a plenoptic imaging scheme whereby the focus of a captured image of a scene can be changed during post-processing, which may obviate a mechanical focus system. This capability may be of particular value in automated vision systems such as, for example, automobile-mounted pedestrian avoidance systems.

The modular packaging and optical system also enables super-resolution imaging capabilities. The effective resolution of the overall camera core may exceed the native resolution of the individual constitutive FPA sub-arrays. Under this scheme, scene data from multiple FPA sub-arrays covering substantially overlapping fields of view are combined during post-processing to create a high-resolution image.

Accordingly, the scope of the invention should be determined by the following claims and their legal equivalents.

What is claimed is:

1. A method for producing a focal plane array of pixels for detecting electromagnetic radiation, the method comprising the steps of:
a) batch-fabricating a plurality of unit cells on at least one wafer, wherein each of the unit cells comprises a sub-array of pixels, and adjacent unit cells have a first spacing from each other on the wafer;
b) singulating the unit cells; and
c) arranging individual ones of the singulated unit cells into a group on a carrier substrate such that the spacing between adjacent unit cells on the carrier substrate is greater than the first spacing on the wafer.

2. The method of claim 1, wherein at least one of the unit cells arranged on the carrier substrate has a different number or type of pixels than does another one of the unit cells arranged on the carrier substrate.

3. The method of claim 1, wherein at least one of the unit cells comprises a sub-array of pixels sensitive to long wavelength infrared (LWIR) radiation, and at least one other of the unit cells comprises a sub-array of pixels that is sensitive to visible light, near-infrared (NIR) radiation, or ultraviolet (UV) radiation.

4. The method of claim 1, wherein at least one of the unit cells comprises a sub-array of pixels sensitive to a first wavelength range of the electromagnetic radiation, at least one other of the unit cells comprises a sub-array of pixels that is sensitive to a second wavelength range of the electromagnetic radiation, and the first wavelength range is different than the second wavelength range.

5. The method of claim 4, wherein the wavelength ranges are selected from the group consisting of the long wave infrared (LWIR) wavelength range, the visible light wavelength range, the near-infrared (NIR) wavelength range, and the ultraviolet (UV) wavelength range.

6. The method of claim 1, wherein the carrier substrate has electrical connections for routing signals between the unit cells and the carrier substrate, and the electrical connections are arranged such that the signals from a plurality of the unit cells are multiplexed to a common signal processor on the carrier substrate.

7. An imaging device comprising:
a) a focal plane array of pixels for detecting electromagnetic radiation, the focal plane array comprising a plurality of singulated unit cells that are arranged in a group on a carrier substrate, wherein each of the unit cells includes a plurality of pixels that form a sub-array of the pixels in the focal plane array when the unit cells are arranged on the carrier substrate;
b) at least one lens positioned to direct incident electromagnetic radiation to the unit cells; and
c) electrical connections for routing signals from the unit cells to the carrier substrate.

8. The device of claim 7, wherein at least one of the unit cells has a different number or type of pixels than does another one of the unit cells arranged on the carrier substrate.

9. The device of claim 7, wherein at least one of the unit cells comprises a sub-array of pixels sensitive to long wavelength infrared (LWIR) radiation, and at least one other of the unit cells comprises a sub-array of pixels that is sensitive to visible light, near-infrared (NIR) radiation, or ultraviolet (UV) radiation.

10. The device of claim 7, wherein at least one of the unit cells comprises a sub-array of pixels sensitive to a first wavelength range of the electromagnetic radiation, at least one other of the unit cells comprises a sub-array of pixels that is sensitive to a second wavelength range of the electromagnetic radiation, and the first wavelength range is different than the second wavelength range.

11. The device of claim 10, wherein the wavelength ranges are selected from the group consisting of the long wave infrared (LWIR) wavelength range, the visible light wavelength range, the near-infrared (NIR) wavelength range, and the ultraviolet (UV) wavelength range.

12. The device of claim 7, wherein the device comprises a plurality of lenses, each of the lenses is positioned to direct the incident electromagnetic radiation to a respective one of the unit cells or to a respective group of the unit cells, and at least two of the lenses have different relative apertures (F/#).

13. The device of claim 7, wherein the device comprises a plurality of lenses, each of the lenses is positioned to direct the incident electromagnetic radiation to a respective one of the unit cells or to a respective group of the unit cells, and at least two of the lenses are arranged such that they have different orientations of their optical axes.

14. The device of claim 7, wherein the device comprises a plurality of lenses, each of the lenses is positioned to direct the incident electromagnetic radiation to a respective one of the unit cells or to a respective group of the unit cells, and at least two of the lenses have different material composition or diameter.

15. The device of claim 7, further comprising at least one lens substrate holding the at least one lens in position to direct the electromagnetic radiation to the unit cells, wherein the lens substrate is arranged with the carrier substrate to enclose the focal plane array in a vacuum in a space between the lens substrate and the carrier substrate.

16. The device of claim 15, wherein the lens substrate has a plurality of windows with ledges for holding an array of lenses.

17. The device of claim 15, wherein the lens substrate is arranged with the carrier substrate by means of at least one standoff structure positioned between the lens substrate and the carrier substrate such that the standoff structure forms walls around the periphery of the enclosed space between the lens substrate and the carrier substrate.

18. The device of claim 7, wherein the carrier substrate has electrical connections for routing signals between the unit cells and the carrier substrate, and the electrical connections are arranged such that the signals from a plurality of the unit cells are multiplexed to a common signal processor on the carrier substrate.

19. The device of claim 7, wherein the carrier substrate has electrical connections for routing signals between the unit cells and the carrier substrate, the device further comprises at least one processor arranged to receive the signals, and the processor is programmed to construct an image from the signals.

20. A camera incorporating the imaging device of claim 7.

21. A method for producing a lens array comprising the steps of:
a) batch-fabricating a plurality of lenslets on one or more wafers;
b) singulating the lenslets; and
c) forming the lens array by arranging a plurality of the singulated lenslets on a carrier substrate.

22. The method of claim 21, wherein the carrier substrate has windows with ledges for holding the lenslets.

23. The method of claim 21, wherein the lenslets comprise etched silicon.

24. The method of claim 21, wherein the lenslets comprise chalcogenide glass.

25. The method of claim 21, wherein at least two of the lenslets have different relative apertures (F/#).

26. The method of claim 21, wherein at least two of the lenslets are arranged such that they have different orientations of their optical axes.

27. The method of claim 21, wherein at least two of the lenslets have different material composition or diameter.

28. The method of claim 21, wherein adjacent lenslets have a first spacing from each other on the wafer, and the lenslets are arranged on the carrier substrate such that the spacing between adjacent lenslets on the carrier substrate is greater than the first spacing on the wafer.
